(19) United States
(12) Patent Application Publication
(10) Pub. No.: US 2005/0068751 A1
(43) Pub. Date: Mar. 31, 2005

(54) Floating trace on signal layer

(76) Inventors: Hyunjun Kim, Chandler, AZ (US); Jiangqi He, Gilbert, AZ (US); Yuan-Liang Li, Chandler, AZ (US); Prashant Parmar, Gilbert, AZ (US)

Correspondence Address: Buckley, Maschoff, Talwalkar & Allison LLC, Five Elm Street, New Canaan, CT, 06840, US

(21) Appl. No.: 10/674,886

(22) Filed: Sep. 30, 2003

(51) Int. Cl. H05K 7/06

(52) U.S. Cl. 361/780; 174/255; 174/262; 361/794

(57) ABSTRACT

According to some embodiments, a floating trace is provided on a signal layer (e.g., of a printed circuit board).

### BACKGROUND

A printed circuit board may have a “signal layer” with signal traces (e.g., conductive paths) that electrically connect components, such as processors and other integrated circuits. The printed circuit board may also have one or more voltage planes, such as a power plane and a ground plane, to provide power to the components.

In some cases, electromagnetic resonance between voltage planes (e.g., between a power plane and a ground plane) may increase the impedance associated with a printed circuit board. For example, reflections back and forth between the edges of a power plane and a ground plane can result in electromagnetic resonance that increases the impedance characteristics of a printed circuit board.

To reduce the resonance and improve impedance characteristics, passive elements, such as surface mounted capacitors, can be provided on the printed circuit board. This approach, however, may increase the cost of the printed circuit board—especially when the design needs to meet requirements associated with a high-performance processor (e.g., a processor with a high frequency clock signal might require a large number of surface mounted capacitors).

### BRIEF DESCRIPTION OF THE DRAWINGS

FIG. 1 is a side view of a printed circuit board.

FIG. 2 is a side view of an apparatus according to some embodiments.

FIG. 3 is a top view of an apparatus according to some embodiments.

FIG. 4 is a flow chart of a method according to some embodiments.

FIG. 5 is an example of printed circuit board according to some embodiments.

FIG. 6 is a block diagram of a system according to some embodiments.

### DETAILED DESCRIPTION

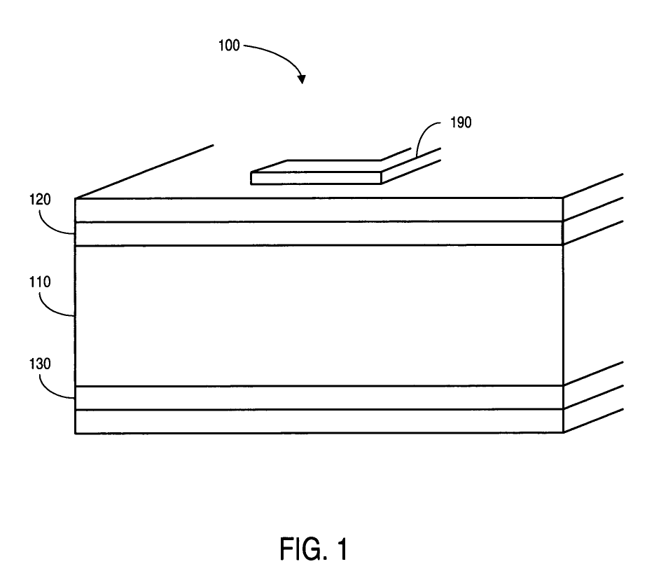

FIG. 1 is a side view of a printed circuit board 100. The printed circuit board 100 is formed of a dielectric material 110 (e.g., a material that is not electrically conductive). A first voltage plane 120 and a second voltage plane 130 are formed in the dielectric material 110. For example, the first voltage plane 120 might be a +5 Volt (V) power plane while the second voltage plane 130 is a ground plane (e.g., at 0 V).

The printed circuit board 100 also includes a signal layer (the top surface) with signal traces 190 (e.g., conductive paths) that electrically connect components, such as processors and other integrated circuits. In some cases, electromagnetic resonance between the voltage planes 120, 130 may increase the impedance associated with the printed circuit board 100.

To reduce the resonance and improve impedance characteristics, discrete passive elements (e.g., resistors and capacitors) might be used to terminate the edges of the voltage planes 120, 130. This approach, however, might increase the cost of the printed circuit board 100.

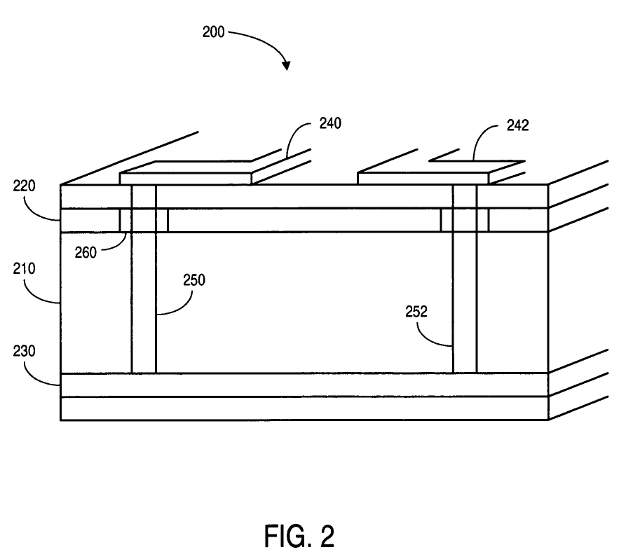

FIG. 2 is a side view of an apparatus 200 according to some embodiments. The apparatus 200 may be, for example, a printed circuit board associated with a Flip Chip Ball Grid Array (FCBGA) or Pin Grid Array (PGA) package model. As before, the apparatus 200 includes a dielectric material 210 in which a first voltage plane 220 and a second voltage plane 230 are formed. For example, the first voltage plane 220 might be a power plane and the second voltage plane 230 might be a ground plane. Similarly, the first voltage plane 220 might be a ground plane and the second voltage plane 230 might be a power plane. The apparatus 200 also includes a signal layer (the top surface) with signal traces (not illustrated in FIG. 2).

According to some embodiments, a floating trace 240 is provided on the signal layer. The floating trace 240 is an electrically conductive path, such as a strip line or a microstrip line routed along the signal layer, that is electrically connected to the second voltage plane 230. For example, the floating trace 240 might be electrically connected to the second voltage plane 230 via a plated through hole 250 (e.g., that passes through a hole 260 in the first voltage plane 220). Note that the signal layer may include an number of floating traces (with each trace being electrically connected to the second voltage plane 230 and not being directly connected other traces on the signal layer). For example, a second floating trace 242 is illustrated in FIG. 2 as being connected to the second voltage plane 230 via a second plated through hole 252.

Note that the floating trace 240 may have a resistance that is (i) proportional to the length of the trace 240 and (ii) inversely proportional to the cross-sectional area of the trace 240. Moreover, the substrate between the traces 240, 242 may inherently provide some capacitance. As a result, the overall impedance associated with the apparatus 200 may be damped or reduced, especially at resonant frequencies, without using discrete passive components (e.g., surface mounted resistors and capacitors). That is, the parasitic resistance and capacitance associated with the floating traces 240, 242 may improve the efficiency of the power delivery system (e.g., the voltage planes 220, 230).

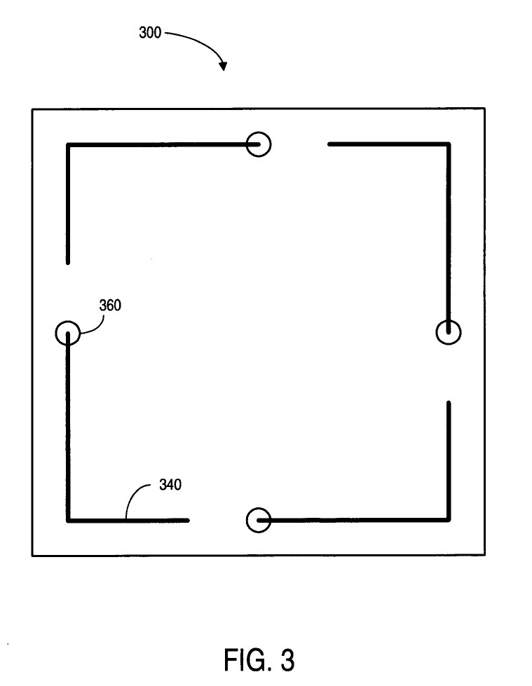

FIG. 3 is a top view of an apparatus 300 (e.g., illustrating the signal layer of a printed circuit board) according to some embodiments. In particular, four floating traces 340 are routed on the signal layer and are electrically coupled to a voltage plane via plated through holes 360. The signal layer would also include signal lines and/or components (not illustrated in FIG. 3). Note that increasing the number of floating traces 340 might further reduce resonance and/or the impedance characteristics of the apparatus 300.

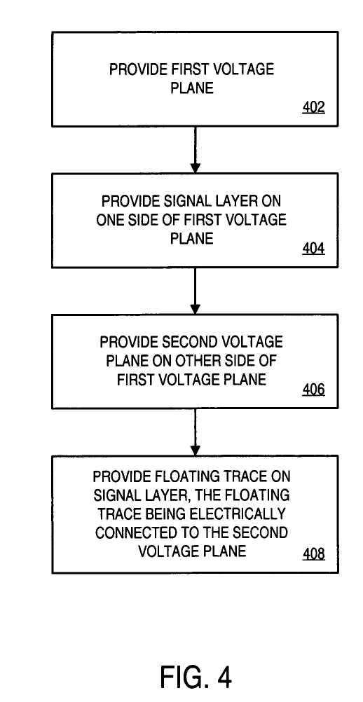

FIG. 4 is a flow chart of a method according to some embodiments. The flow chart does not necessarily imply a fixed order to the actions, and embodiments may be performed in any order that is practicable. At 402, a first voltage plane is provided. At 404, a signal layer is provided on one side of the first voltage plane, and a second voltage plane is provided on the other side of the first voltage plane at 406. At 408, a floating trace is provided on the signal layer, the floating trace being electrically connected to the second voltage plane. For example, a microstrip line may be provided on the signal layer. According to some embodiments, the floating traces are positioned in the signal layer so as to reduce cross-talk with one or more neighboring signal lines.

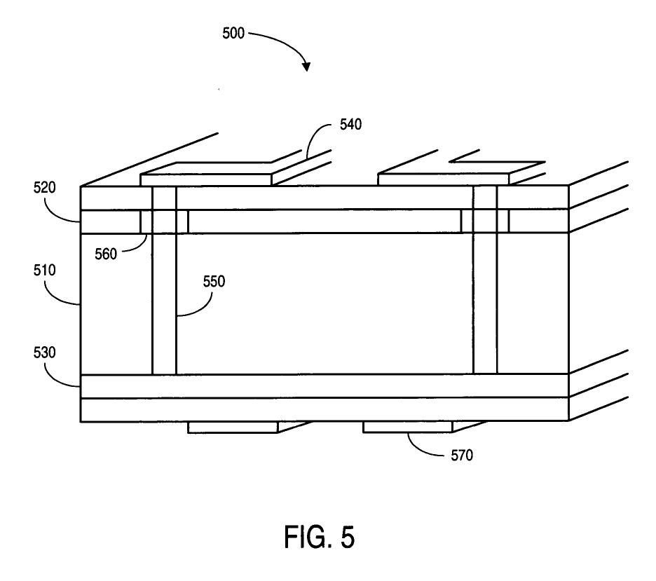

FIG. 5 is an example of printed circuit board 500 including a dielectric material 510 in which a power plane 520 and a ground plane 530 are formed. The power and ground planes 520, 530 might be, for example, 30 micrometers (μm) thick sheets of conductive material that are separated by 800 μm of dielectric material.

The printed circuit board 500 also includes a signal layer (the top surface) with signal traces (not illustrated in FIG. 5). According to some embodiments, microstrip lines 540 are provided on the signal layer and are electrically connected to the ground plane 530 via plated through holes 550 that pass through holes 560 in the power plane 520. The microstrip lines 540 might be, for example, 15 μm thick. Although two microstrip lines 540 are illustrated in FIG. 5, any number of microstrip lines 540 might be provided on the signal layer. The microstrip lines 540 may, for example, improve the impedance characteristics of the printed circuit board 500 by reducing electromagnetic resonance between the power plane 520 and the ground plane 530.

As illustrated in FIG. 5, the printed circuit board 500 includes a second signal layer with signal traces 570. Note that the second signal layer might also include floating traces (which are not illustrated in FIG. 5).

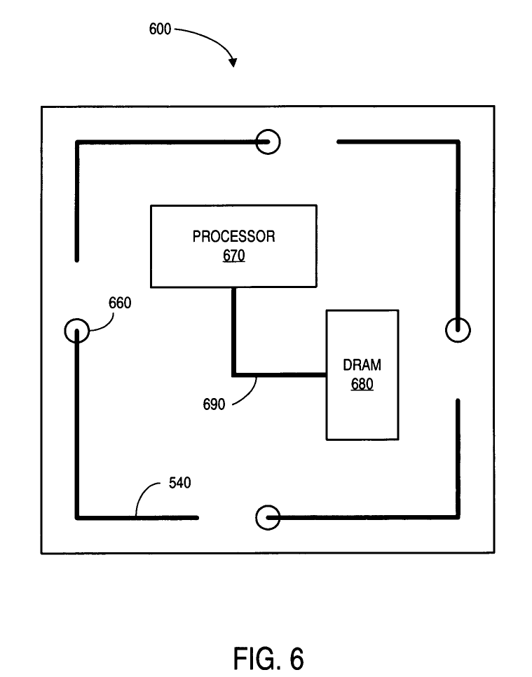

FIG. 6 is a block diagram of a system 600 according to some embodiments. In particular, a top view of a printed circuit board illustrates floating traces 640 that are electrically coupled to a voltage plane (not illustrated in FIG. 6) via plated through holes 660. Moreover, a processor 670, such as an INTEL® PENTIUM® 4 processor, and a Dynamic Random Access Memory (DRAM) unit 680 are coupled to the printed circuit board and are connected to each other via a signal line 690.

The following illustrates various additional embodiments. These do not constitute a definition of all possible embodiments, and those skilled in the art will understand that many other embodiments are possible. Further, although the following embodiments are briefly described for clarity, those skilled in the art will understand how to make any changes, if necessary, to the above description to accommodate these and other embodiments and applications.

Although some embodiments have been described with respect to a power plane and/or a ground plane, any type of voltage plane may be associated with a floating trace on a signal layer. Moreover, although specific components have been used as examples, a floating trace may be associated with any type of component, including an Application Specific Integrated Circuit (ASIC), a processor such as a Central Processing Unit (CPU), a memory device, a package, a chipset, a and/or a motherboard. Similarly, although specific routing paths and geometries have been illustrated for a floating trace, floating traces may be routed along any path in the signal layer.

The several embodiments described herein are solely for the purpose of illustration. Persons skilled in the art will recognize from this description other embodiments may be practiced with modifications and alterations limited only by the claims.

1. An apparatus, comprising:
a first voltage plane;
a signal layer on one side of the first voltage plane;
a second voltage plane on the other side of the first voltage plane; and
a floating trace on the signal layer, wherein the floating trace is electrically connected to the second voltage plane.

2. The apparatus of claim 1, wherein the first voltage plane is a power plane and the second voltage plane is a ground plane.

3. The apparatus of claim 1, wherein the first voltage plane is a ground plane and the second voltage plane is a power plane.

4. The apparatus of claim 1, wherein the signal layer includes a plurality of floating traces, each floating trace being (i) electrically connected to the second voltage plane and (ii) not directly connected to other floating traces on the signal layer.

5. The apparatus of claim 1, wherein the floating trace and the second voltage plane are electrically connected via a plated through hole.

6. The apparatus of claim 1, wherein the floating trace is a microstrip line.

7. The apparatus of claim 6, wherein the microstrip line provides impedance damping.

8. The apparatus of claim 6, wherein the microstrip line reduces resonance between the first voltage plane and the second voltage plane.

9. The apparatus of claim 1, wherein the first voltage plane, the signal layer, and the second voltage plane are separated by a dielectric material.

10. The apparatus of claim 1, wherein the apparatus is a printed circuit board.

11. The apparatus of claim 10, wherein the printed circuit board is associated with at least one of: (i) a flip chip ball grid array package model, and (ii) a pin grid array package model.

12. The apparatus of claim 1, further comprising:
a second signal layer.

13. The apparatus of claim 12, further comprising:
a second floating trace on the second signal layer.

14. A method, comprising:
providing a first voltage plane;
providing a signal layer on one side of the first voltage plane;
providing a second voltage plane on the other side of the first voltage plane; and
providing a floating trace on the signal layer, wherein the floating trace is electrically connected to the second voltage plane.

15. The method of claim 14, further comprising:
positioning the floating trace in the signal layer to reduce cross-talk with a neighboring signal line.

16. The method of claim 14, further comprising:
providing a second signal layer; and
providing a second floating trace on the second signal layer.

17. The method of claim 14, wherein providing the floating trace comprising:
providing a microstrip line on the signal layer.

18. A printed circuit board, comprising:
a signal layer including a plurality of microstrip lines that are not electrically connected to each other on the signal layer;
a power plane under the signal layer and separated from the signal layer by a dielectric material;
a ground plane under the power plane and separated from the power plane by the dielectric material,
wherein each of the microstrip lines is (i) electrically connected to the ground plane via a plated through hole passing through the dielectric material and the power plane and (ii) not directly connected to other microstrip lines on the signal layer.

19. The printed circuit board of claim 18, wherein the microstrip lines provide impedance damping and reduce resonance between the power plane and the ground plane.

20. A system, comprising:
a printed circuit board, including:
a first voltage plane,
a signal layer on one side of the first voltage plane,
a second voltage plane on the other side of the first voltage plane, and
a floating trace on the signal layer, wherein the floating trace is electrically connected to the second voltage plane; and
a dynamic random access memory unit coupled to the printed circuit board.

21. The system of claim 20, further comprising:
a processor coupled to the printed circuit board, wherein the processor and dynamic random access memory unit are to exchange information via signal lines on the signal layer.
